(19) United States
(12) Patent Application Publication
(10) Pub. No.: US 2013/0113006 A1
(43) Pub. Date: May 9, 2013

(54) SEMICONDUCTOR LIGHT EMITTING DEVICE AND FABRICATION METHOD THEREOF

(71) Applicant: SAMSUNG ELECTRONICS CO., LTD., Suwon-si (KR)

(72) Inventors: Tae Hun KIM, Gyeonggi-do (KR); Gi Bum KIM, Gyeonggi-do (KR); Bum Joon KIM, Seoul (KR); Seung Wan CHAE, Gyeonggi-do (KR); Su Hyun JO, Seoul (KR); Sang Yeob SONG, Gyeonggi-do (KR)

(73) Assignee: SAMSUNG ELECTRONICS CO., LTD., Suwon-si, Gyeonggi-do (KR)

(21) Appl. No.: 13/670,129

(22) Filed: Nov. 6, 2012

(30) Foreign Application Priority Data
Nov. 7, 2011 (KR) 10-2011-0114927

(51) Int. Cl. H01L 33/60

(52) U.S. Cl. 257/98; 438/29; 257/E33.067

(57) ABSTRACT

A semiconductor light emitting device include an n-type semiconductor layer, an active layer disposed on the n-type semiconductor layer, and a first p-type semiconductor layer disposed on the active layer. The first p-type semiconductor layer has an uneven structure formed on a surface thereof. A second p-type semiconductor layer has an impurity concentration higher than that of the first p-type semiconductor layer. The second p-type semiconductor layer is disposed on the first p-type semiconductor layer and has an uneven structure formed on a surface thereof. A reflective metal layer is formed on the second p-type semiconductor layer.

### CROSS-REFERENCE TO RELATED APPLICATIONS

This application claims the priority to Korean Patent Application No. 10-2011-0114927 filed on Nov. 7, 2011, in the Korean Intellectual Property Office, the disclosure of which is incorporated herein by reference.

### TECHNICAL FIELD

The present application relates to a semiconductor light emitting device and a fabrication method thereof.

### BACKGROUND

An LED, a semiconductor light emitting device, refers to a device generating light energy according to electron-hole recombination when an electrical current is applied thereto, by using the characteristics of a p-n junction structure. Namely, when a forward voltage is applied to a semiconductor formed of a particular element, electrons and holes, moving through a junction of a positive electrode and a negative electrode, are recombined, and here, the recombined electrons and holes have an energy level lower than that of the case in which they were in when alone (separated), making a difference in energy levels, and light is emitted due to the difference of energy levels.

Here, light is generated from an active layer, passes through respective laminates (or respective lamination bodies) constituting a light emitting device, and is finally emitted to the outside. In this case, in order to enhance luminous efficiency, a method of forming a reflective structure at one side of a light emitting device to guide light in one direction, or the like, is used. Here, even if such a reflective structure employs a metal having a high level of reflectance (or reflectivity), as the reflectance is increased to a level as high as 90%, luminance efficiency of the device can be enhanced. Thus, previously, there have been attempts to enhance the reflectivity and reliability of a reflective structure included in a device.

A need still exists to provide a semiconductor light emitting device and fabrication method thereof having a reflective structure with improved reflecting performance.

### SUMMARY

An aspect of the present application provides a semiconductor light emitting device including a reflective structure having excellent reflecting performance.

Another aspect of the present application provides a method of effectively fabricating a semiconductor light emitting device having the foregoing structure.

According to an aspect of the present application, there is provided a semiconductor light emitting device. The device includes an n-type semiconductor layer, an active layer formed on the n-type semiconductor layer, a first p-type semiconductor layer formed on the active layer. The first p-type semiconductor layer has an uneven structure disposed on a surface thereof A second p-type semiconductor layer has an impurity concentration higher than that of the first p-type semiconductor layer. The second p-type semiconductor layer is disposed on the first p-type semiconductor layer and has an unevenness structure formed on a surface thereof. A reflective metal layer is disposed on the second p-type semiconductor layer.

The uneven structure of the second p-type semiconductor layer may have a shape corresponding to the uneven structure of the first p-type semiconductor layer.

The reflective metal layer may have an uneven structure formed on a surface thereof.

The uneven structure of the reflective metal layer may have a shape corresponding to the uneven structure of the second p-type semiconductor layer.

The semiconductor light emitting device may further include a conductive substrate formed on the reflective metal layer.

The semiconductor light emitting device may further include a conductive adhesive layer disposed between the reflective metal layer and the conductive substrate, and the conductive adhesive layer may be formed to fill the uneven structure of the reflective metal layer.

The semiconductor light emitting device may further include at least one conductive via connecting the n-type semiconductor layer and the conductive substrate through the active layer, the first p-type semiconductor layer, the second p-type semiconductor layer, and the reflective layer.

The conductive via may include an uneven structure formed on an interface of the n-type semiconductor layer.

The semiconductor light emitting device may further include an insulating region formed between each of the active layer, the first p-type semiconductor layer, the second p-type semiconductor layer, and the reflective layer and the conductive vias.

According to another aspect of the present application, there is provided a method of fabricating a semiconductor light emitting device. The method includes disposing an n-type semiconductor layer on a substrate; disposing an active layer on the n-type semiconductor layer; and disposing a first p-type semiconductor layer on the active layer. A mask having open regions exposing portions of an upper surface of the first p-type semiconductor layer is disposed on the first p-type semiconductor layer The first p-type semiconductor layer is etched through the open regions to form an uneven structure. A second p-type semiconductor layer is disposed on the first p-type semiconductor layer such that the second p-type semiconductor layer has an impurity concentration higher than that of the first p-type semiconductor layer. The second p-type semiconductor layer second p-type semiconductor layer has an uneven structure formed on a surface thereof. A reflective metal layer is disposed on the second p-type semiconductor layer.

The step of disposing the mask may include: disposing a metal layer on the first p-type semiconductor layer; and making the metal layer cohere to form a plurality of clusters.

The metal layer may have a thickness ranging from 10 Å to 250 Å.

The step of making the metal layer cohere may be performed by thermally treating the metal layer.

The step of disposing the metal layer may be performed through E-beam evaporation.

The uneven structure of the second p-type semiconductor layer may have a shape corresponding to the uneven structure of the first p-type semiconductor layer.

The reflective metal layer may have an uneven structure formed on a surface thereof.

The uneven structure of the reflective metal layer may have a shape corresponding to the uneven structure of the second p-type semiconductor layer.

The method may further include: disposing a conductive substrate on the reflective metal layer.

The method may further include: separating the substrate from the n-type semiconductor layer.

The method may further include: removing the mask after forming the unevenness structure by etching the first p-type semiconductor layer.

The removing of the mask may include removing an oxide formed on a surface of the first p-type semiconductor layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a cross-sectional view schematically illustrating a semiconductor light emitting device according to an example of the present application;

FIG. 2 is a cross-sectional view schematically illustrating a semiconductor light emitting device according to a modification of the example of FIG. 1;

FIGS. 3, 4, 5, 6, 7, 8 and 9 are cross-sectional views schematically illustrating sequential processing steps of a method of fabricating a semiconductor light emitting device according to an example of the present application; and

FIGS. 10, 11, 12 and 13 are cross-sectional views schematically illustrating sequential processes of a method of fabricating a semiconductor light emitting device according to another example of the present application.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

Examples of the present application will now be described in detail with reference to the accompanying drawings.

The application may, however, be exemplified in many different forms and should not be construed as being limited to the examples set forth herein. Rather, these examples are provided so that this disclosure will be thorough and complete, and will fully convey the scope of the application to those of ordinary skill in the art. In the drawings, the shapes and dimensions of elements may be exaggerated for clarity, and the same reference numerals will be used throughout to designate the same or like components.

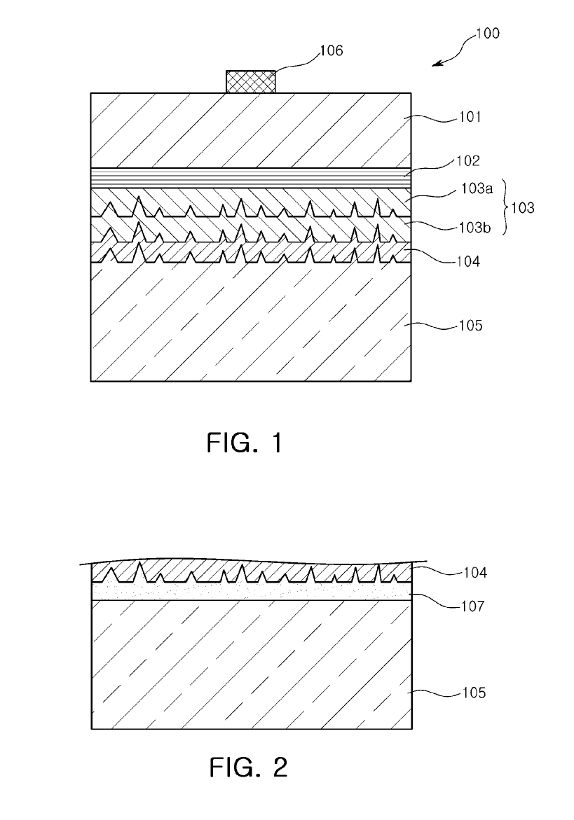

FIG. 1 is a cross-sectional view schematically illustrating a semiconductor light emitting device according to an example of the present application. FIG. 2 is a cross-sectional view schematically illustrating a semiconductor light emitting device according to a modification of the example of FIG. 1. Specifically, FIG. 2 shows a portion of the periphery of a reflective metal layer and a conductive substrate.

With reference to FIG. 1, a semiconductor light emitting device 100 according to the present example may include an n-type semiconductor layer 101, an active layer 102, a first p-type semiconductor layer 103a, a second p-type semiconductor layer 103b, and a reflective metal layer 104. Based on FIG. 1, a conductive substrate 105 is disposed beneath (or at a lower portion of) the reflective metal layer 104, and an n-type electrode 106 may be disposed on (or at an upper portion of) the n-type semiconductor layer 101. Here, terms such as ‘upper portion’, ‘upper surface’, ‘lower portion’, ‘lower surface’, ‘lateral surface’, or the like, are used based on the directionality of the drawings, which may be changed according to the direction in which the device is actually disposed in use.

First, a light emitting structure, i.e., a structure including the n-type and p-type semiconductor layers 101 and 103 and the active layer 102 disposed therebetween will be described. The n-type and p-type semiconductor layers 101 and 103 may be made of a nitride semiconductor, e.g., a material having a composition of AlₓIn_{y}Ga_{1-x-y}N (0≦x≦1, 0≦y≦1, 0≦x+y≦1). Alternatively, the n-type and p-type semiconductor layers 101 and 103 may be made of an AlInGaP or an AlInGaAs-based material. The active layer 102, disposed between the n-type and p-type semiconductor layers 101 and 103 emits light having a certain energy level according to the recombination of electrons and holes and may have a multi-quantum well (MQW) structure in which quantum well layers and quantum barrier layers are alternately laminated. Meanwhile, the n-type and p-type semiconductor layers 101 and 103 and the active layer 102 constituting the light emitting structure may be grown by using a conventional process, such as metal organic chemical vapor deposition (MOCVD), hydride vapor phase epitaxy (HVPE), molecular beam epitaxy (MBE), and the like.

In the present example, the p-type semiconductor layer 103 includes the first and second p-type semiconductor layers 103a and 103b having different impurity concentrations, and an uneven structure (i.e., a structure having depressions and protrusions) is disposed on the surfaces of the first and second p-type semiconductor layers 103a and 103b. In detail, the second p-type semiconductor layer 103b has an impurity concentration higher than that of the first p-type semiconductor layer 103a, and here, since the impurity concentration of the second p-type semiconductor layer 103b in contact with the reflective metal layer 104 is high, electrical characteristics can be enhanced. Due to the uneven structure formed on the surfaces of the first and second p-type semiconductor layers 103a and 103b, reflective efficiency of the underlying reflective metal layer 104 can be enhanced. Namely, in comparison to a structure having a flat reflective surface, light emitted from the active layer 102 may be reflected in various paths by the reflective surface with depressions and protrusions formed thereon, thereby increasing the quantity of light emitted to the outside. In this case, the depressions and protrusions of the uneven structure of the first and second p-type semiconductor layers 103a and 103b may have an irregular size and spacing, and such an irregular, uneven structure may be obtained by using a metal agglomerate mask.

As for the formation of the uneven structure, in the present example, the uneven structure is formed to start from the first p-type semiconductor layer 103a. When an etching process is applied to form an uneven structure on the second p-type semiconductor layer 103b, it may be difficult for the second p-type semiconductor layer 103b to be in ohmic-contact with the reflective metal layer 104. Thus, after the uneven structure is formed on the first p-type semiconductor layer 103a, the second p-type semiconductor layer 103b is doped to have an impurity concentration higher than that of the first type semiconductor layer 103a, and in this case, as shown in FIG. 1, the uneven structure of the second p-type semiconductor layer 103b may be formed to correspond to that of the first p-type semiconductor layer 103a. A process of forming the uneven structures of the first and second p-type semiconductor layers 103a and 103b is described later.

The reflective metal layer 104 may be made of a metal having a high level of reflectivity, namely, a material having electrically ohmic characteristics with the p-type semiconductor layer 103, in particular, with the second p-type semiconductor layer 103b. In consideration of this function, the reflective metal layer 104 may be formed to include silver (Ag), nickel (Ni), aluminum (Al), rhodium (Rh), palladium (Pd), iridium (Ir), ruthenium (Ru), magnesium (Mg), zinc (Zn), platinum (Pt), gold (Au), or the like. The reflective metal layer 104 reflects light emitted from the active layer 102, and a reflective surface of the reflective metal layer 104 has an uneven shape due to the uneven structure of the second p-type semiconductor layer 103b. Also, as shown in FIG. 1, the reflective metal layer 104 may have an uneven structure having a shape corresponding to the uneven structure of the second p-type semiconductor layer 103b on a surface thereof (i.e., the surface facing the conductive substrate in FIG. 1). Here, however, the uneven structure formed on the surface of the reflective metal layer 104 is not essential and may not be provided according to examples of the present application.

The conductive substrate 105 may be formed beneath the reflective metal layer 104 based on FIG. 1 and connected to an external power supply to apply an electrical signal to the p-type semiconductor layer 103. Also, the conductive substrate 105 may serve as a support for supporting the light emitting structure during a process such as a laser lift-off process, or the like The conductive substrate 105 may be made of a material including any one of gold (Au), nickel (Ni), aluminum (Al), copper (Cu), tungsten (W), silicon (Si), selenium (Se), and gallium arsenide (GaAs), e.g., a material doped with aluminum (Al) on a silicon (Si) substrate. The conductive substrate 105 may be formed on the reflective metal layer 104 through a process such as plating, sputtering, deposition, or the like, and alternatively, a previously fabricated conductive substrate 105 may be bonded to the reflective metal layer 104 by the medium of a conductive adhesive layer 107, or the like. In this case, the conductive adhesive layer 107 may be formed to fill the unevenness structure of the reflective metal layer 104, and accordingly, adhesive strength between the reflective metal layer 104 and the conductive substrate 105 can be enhanced. As the conductive adhesive layer 107, a eutectic metal such as AuSn, or the like, may be used, or a conductive epoxy, or the like, may be used.

The n-type electrode 106 may be connected to an external power supply to apply an electrical signal to the n-type semiconductor layer 101 and may be formed by deposing, sputtering, or the like, a conventional electroconductive material, e.g., one or more of silver (Ag), aluminum (Al), nickel (Ni), chromium (Cr), and the like.

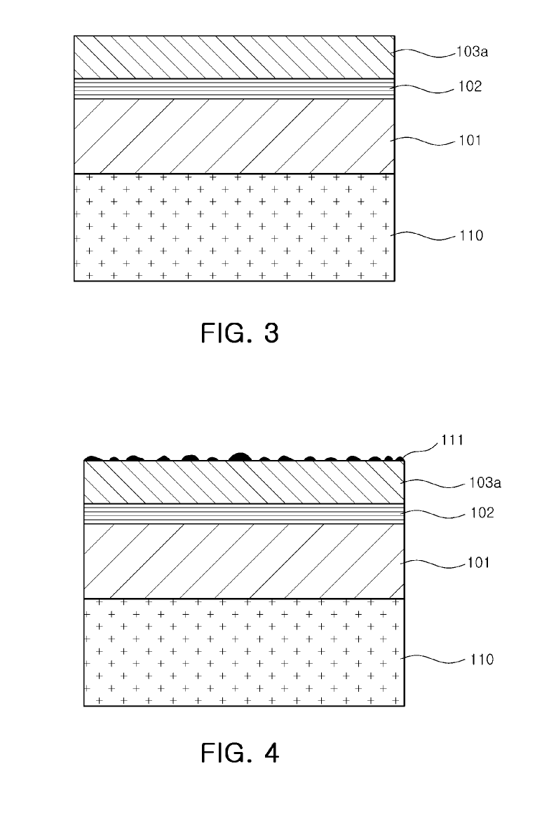

Hereinafter, a method for fabricating a semiconductor light emitting device having the foregoing structure or a structure obtained by modifying the foregoing structure will be described. FIGS. 3 through 9 are cross-sectional views schematically illustrating sequential processes of a method of fabricating a semiconductor light emitting device according to an example of the present application.

First, as shown in FIG. 3, portions, i.e., the n-type semiconductor layer 101, the active layer 102, and the first p-type semiconductor layer 103a, of a light emitting structure are formed on a substrate 110. The substrate 110 is provided as a semiconductor growth substrate. As the substrate 110, a substrate made of an insulating, conductive, or semiconductive material such as sapphire, Si, SiC, MgAl₂O₄, MgO, LiAlO₂, LiGaO₂, GaN, or the like, may be used. In this case, sapphire having electrical insulation characteristics may preferably be used. Sapphire is a crystal having Hexa-Rhombo R3c symmetry, of which lattice constants in c-axis and a-axis directions are 13.001 Å and 4.758 Å, respectively. A sapphire crystal has a C (0001) plane, an A (1120) plane, an R (1102) plane, and the like. In this case, a nitride thin film can be relatively easily formed on the C plane of the sapphire crystal, and because sapphire crystal is stable at high temperatures, it is commonly used as a material for a nitride growth substrate. Meanwhile, a silicon (Si) substrate may also appropriately be used as the substrate 110, and mass-production can be facilitated by using a silicon (Si) substrate which may have a large diameter and is relatively inexpensive.

As described above, the n-type semiconductor layer 101, the active layer 102, and the first p-type semiconductor layer 103a may be formed by using a process such as metal organic chemical vapor deposition (MOCVD), molecular beam epitaxy (MBE), hydride vapor phase epitaxy (HVPE), or the like. Also, although not shown, in order to lessen stress acting on the n-type semiconductor layer 102 to thus enhance crystallinity, a buffer layer having various structures (crystalline, amorphous, or the like) may be formed on the substrate 101 before the n-type semiconductor layer 101 is formed.

Next, as shown in FIG. 4, a mask 111 having open regions exposing portions of the upper surface of the first p-type semiconductor layer 103a are formed on the first p-type semiconductor layer 103a. Any mask may be employed as long as it has open regions, and in the present example, a metal agglomeration mask is used. When a metal agglomeration structure is used in the mask 111, there is no need to use a photolithography pattern, thus achieving excellent productivity and effectively forming an uneven structure.

A method of forming the metal agglomeration structure will be described. The metal agglomeration structure may be obtained by forming a metal layer having an appropriate structure on the first p-type semiconductor layer 103a, and in order to accelerate agglomeration, a heat treatment may be performed thereon. Namely, since the metal layer has high interfacial tension with the first p-type semiconductor layer 103a, when the metal layer is formed to have a small thickness or heated, metal particles are agglomerated to form fine nano-sized aggregations.

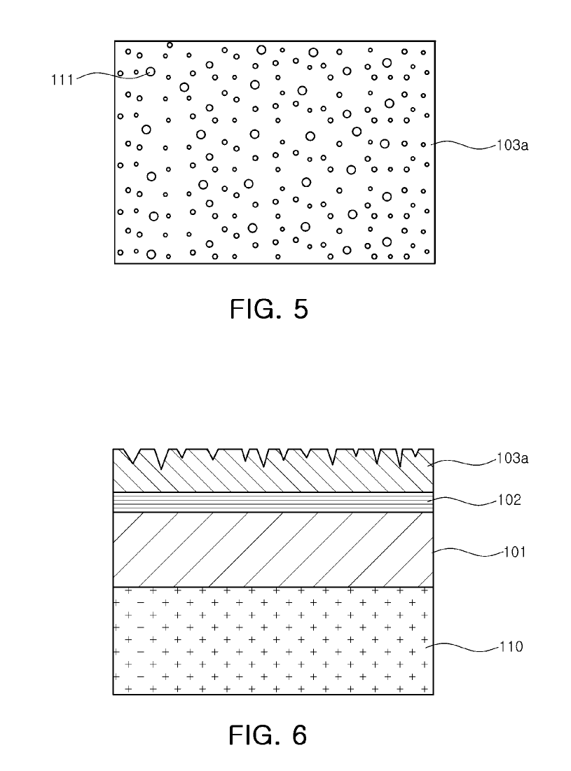

FIG. 5 is a plan view schematically illustrating a mask with metal aggregations having a fine size formed thereon. When the first p-type semiconductor layer 103a is etched by using the mask 111 having the agglomeration structure, a region not exposed by the mask 111 is etched to have an uneven structure. Here, as the aggregations having a finer size are formed, finer uneven structures can be obtained to be advantageous for luminance efficiency. Thus, before forming the mask 111, the metal layer may preferably have a thickness of 250 Å or less, and more preferably, have a thickness of 100 Å or less.

Also, although the metal layer has a relatively small thickness, there is no problem with the formation of fine aggregations, and rather, the thin metal layer may be advantageous for aggregation formation. Thus, there is no limitation on the thickness of the metal layer, but in consideration of processing restrictions, the metal layer may preferably have a thickness of 1 Å or more, and in order to obtain a sufficient amount of metal aggregations, the metal layer may have a thickness of 10 Å or more. The metal layer may be made of a material having qualities of being able to be agglomerated in a direction in which energy is the most stable when deposited with a small thickness, and such a material may be silver (Ag), gold (Au), platinum (Pt), nickel (Ni), ruthenium (Ru), aluminum (Al), cobalt (Co), or the like, and such a metal may be used alone or in an alloy form. In this case, in order to form a thin metal layer, E-beam evaporation may be used.

Meanwhile, in the case of additionally performing a heat treatment to accelerate the formation of the mask 111 having the metal agglomeration structure, the heat treatment may not necessarily be performed at a temperature at which a metal is melted. In general, preferably, the heat treatment may be performed at a temperature of 100° C. or higher, although there may be a difference in temperature depending on metals. Also, when a temperature is excessively high, an underlying transparent electrode layer or the semiconductor layer may be severely thermally damaged, so, preferably, the heat treatment temperature is 1000° C. or lower. Also, heat should be applied for a sufficient period of time to obtain completely formed aggregations. Thus, the heat treatment may be performed for 10 seconds or more. Meanwhile, even in the case that the time for performing the heat treatment is lengthened, the effect may not be increased, and rather, the first p-type semiconductor layer 103a, or the like, may be thermally damaged. Thus, preferably, the time for performing the heat treatment is limited to 10000 seconds or less, and more preferably, is limited to 1000 seconds or less. Thermal treatment may be performed by a general apparatus, e.g., an infrared lamp heating apparatus (e.g., an RTA) or a general furnace. A grain size of the mask 111 having the metal agglomeration structure formed by the heat treatment has a size of 1 μm or less, so an etched pattern obtained by performing etching with the mask may also be formed to have a nano-size, and in addition, the spacings and shapes of the pattern may be irregular.

Next, as shown in FIG. 6, the first p-type semiconductor layer 103a is etched to form the uneven structure on the surface of the first p-type semiconductor layer 103a, and here, etching may be performed through the open regions of the mask 111 as described above. The etching process is not particularly limited to a particular method. For example, a dry etching method using a gas such as Cl₂, BCl₃, CH₄, or the like, may be used. After the unevenness structure is formed on the first p-type semiconductor layer 103a, the mask 111 may be removed. FIG. 6 shows the state without the mask 111. The mask 111 may be removed by using an appropriate etching process, e.g., a wet etching process. In this case, an oxide formed on the surface of the first p-type semiconductor layer 103a may also be removed together during the process of removing the mask 111. Namely, an oxide (e.g., GaO, formed as GaN is exposed to the air) may be generated on the surface of the first p-type semiconductor layer 103a during the formation of the uneven structure, and such an oxide may impede the functioning of the device. Thus, the contaminant on the surface of the first p-type semiconductor layer 103a is also removed together with the mask 111, thus enhancing device reliability.

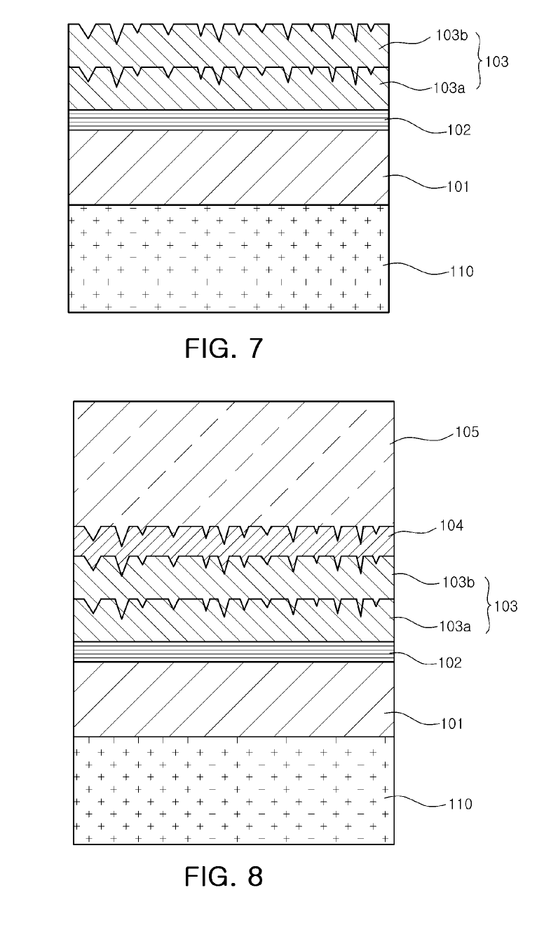

Thereafter, as shown in FIG. 7, the second p-type semiconductor layer 103b is formed on the first p-type semiconductor layer 103a, and as described above, the second p-type semiconductor layer 103b is doped with a relatively large amount of impurities in consideration of electrical characteristics. The second p-type semiconductor layer 103b may have an uneven structure having a shape corresponding to the unevenness structure of the first p-type semiconductor layer 103a on a surface thereof during a growth process, thus having an effective reflective structure as described above. In this case, since the uneven structure can be formed on the second p-type semiconductor layer 103b without performing an etching process, damage that may be otherwise caused when an etching process is applied to the p-type semiconductor can be advantageously eliminated. Thus, the second p-type semiconductor layer 103b not damaged through etching may be easily in ohmic-contact with the reflective metal layer 104, exhibiting excellent characteristics.

Thereafter, as shown in FIG. 8, the reflective metal layer 104 and the conductive substrate 105 are formed on the second p-type semiconductor layer 103b. The reflective metal layer 104 may be formed by performing a process such as deposition, sputtering, or the like, on a highly reflective metal, and since the interface between the reflective metal layer 104 and the second p-type semiconductor layer 103b has the uneven structure, obtaining an effective reflective structure. Also, the reflective metal layer 104 may have an uneven structure having a shape corresponding to the uneven structure of the second p-type semiconductor layer 103b on a surface thereof. Also, as described above, the conductive substrate 105 may be directly formed on the reflective metal layer 104 through plating, deposition, or the like, or may be attached to the reflective metal layer 104 by using a conductive adhesive, or the like.

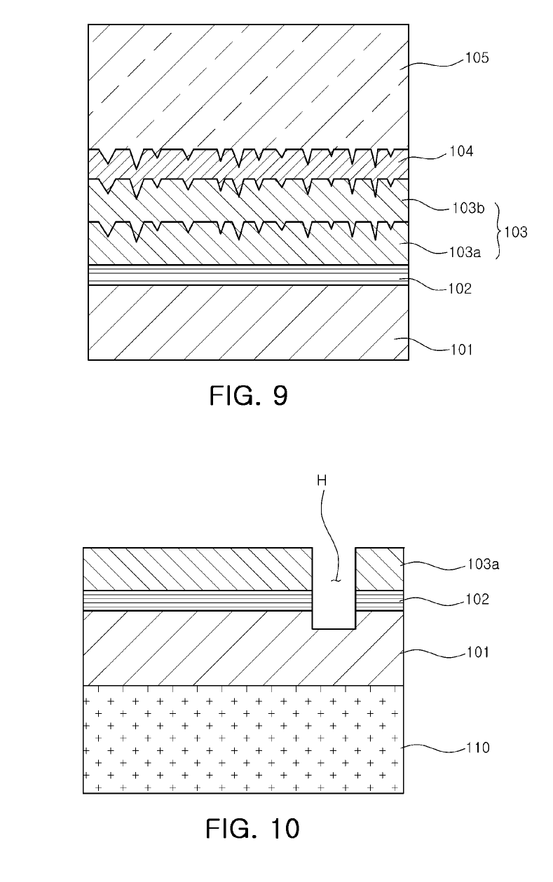

After the conductive substrate 105 is attached, as shown in FIG. 9, the substrate 110 used for growing the semiconductor layers are separated from the n-type semiconductor layer 101, and here, the substrate 110 may be removed by using a process such as a laser lift-off process, a chemical lift-off process, or the like. Also, an electrode may be formed on the n-type semiconductor layer 101 exposed as the substrate 110 was removed to obtain the light emitting device 100 as illustrated in FIG. 1.

Meanwhile, a semiconductor light emitting device having a different structure will be described. FIGS. 10 through 13 are cross-sectional views schematically illustrating sequential processes of a method of fabricating a semiconductor light emitting device according to another example of the present application.

First, after the light emitting structure as described above with reference to FIG. 3 is formed, as shown in FIG. 10, a through hole H is formed in the light emitting structure to expose a portion of the n-type semiconductor layer 101. The through hole H is formed to penetrate the first p-type semiconductor layer 103a and the active layer 102 and serves to form a conductive via (108 in FIG. 12) provided for an electrical connection of the n-type semiconductor layer 101.

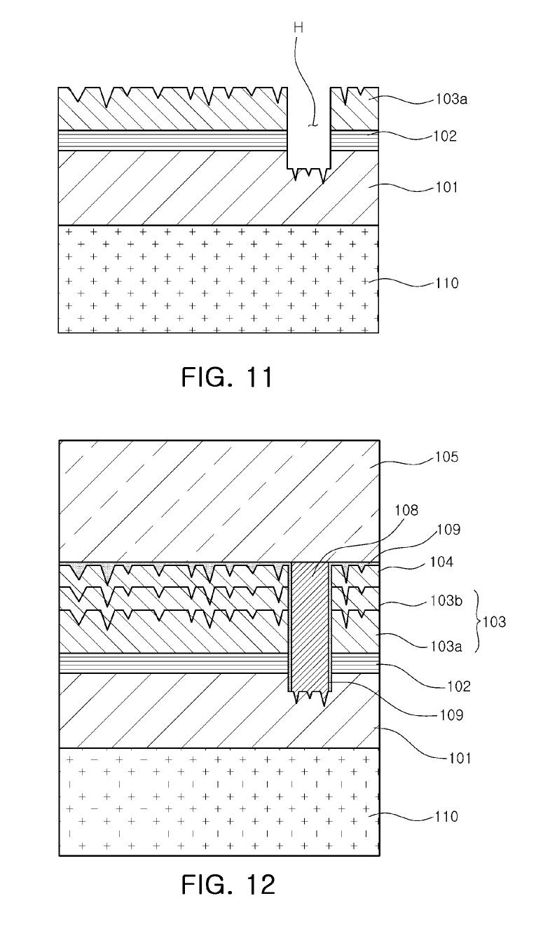

After the formation of the through hole H, as shown in FIG. 11, an uneven structure is formed on the light emitting structure. In detail, an unevenness structure is formed on the surfaces of the first p-type semiconductor layer 103a and the n-type semiconductor layer 101. The uneven structure is formed by using a mask having open regions, and in particular, the surface of the light emitting structure may be effectively etched through a metal agglomeration structure. In this case, since the n-type semiconductor layer 101 is exposed through the through hole H, the mask may be formed on both of the first p-type semiconductor layer 103a and the n-type semiconductor layer 101, and in addition, the etching process may also be simultaneously performed on the first p-type semiconductor layer 103a and the n-type semiconductor layer 101.

Thereafter, as shown in FIG. 12, the reflective metal layer 104 is formed, and in order to prevent an electrical short-circuit, an insulating region 109 is formed on the inner walls of the through hole H and on the surface of the reflective metal layer 104. In order to form the insulating region 109, an electrical insulation material such as a silicon oxide, a silicon nitride, or the like, may be appropriately used. Thereafter, the conductive substrate 105 is disposed on the reflective metal layer 104. Unlike the former example, the conductive substrate 105 is electrically connected to the n-type semiconductor layer 101, and to this end, a conductive via 108 may be included. As described above, the conductive substrate 105 may be made of a material including gold (Au), nickel (Ni), aluminum (Al), copper (Cu), tungsten (W), silicon (Si), selenium (Se), gallium arsenide (GaAs), or the like. The conductive via 108 may be made of the same material as that of the conductive substrate 105, or may be made of a material different from that of the conductive substrate 110 in order to obtain excellent electrical connectivity with the n-type semiconductor layer 101. In this case, one or more conductive vias 108 may be provided to provide better electrical characteristics. Also, the conductive via 108 may include an uneven structure formed on an interface with the n-type semiconductor layer 101 through the foregoing process, and owing to the uneven structure, reflective performance may further enhanced.

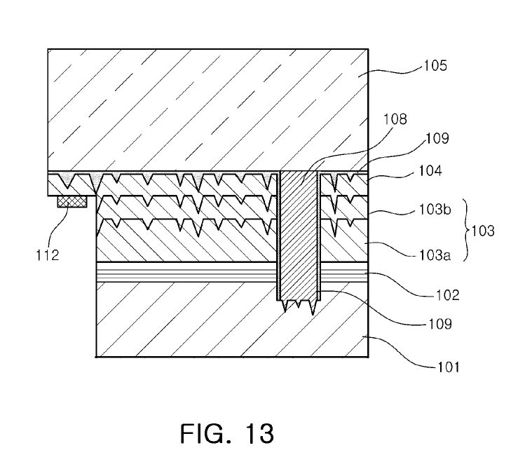

Then, as shown in FIG. 13, the substrate 110 used for growing the semiconductor layers is separated from the light emitting structure, and then, a portion of the light emitting structure is removed to expose the reflective metal layer 104, and a p-type electrode 112 is formed on the reflective metal layer 104. In this case, an electrode may not be formed on a surface of the n-type semiconductor layer 101 and the conductive substrate 105 may serve as an electrode of the n-type semiconductor layer 101, but the present application is not limited thereto.

As set forth above, according to examples of the application, a semiconductor light emitting device including a reflective structure having excellent reflecting performance can be obtained.

In addition, a method of effectively fabricating a semiconductor light emitting device having the foregoing structure can be obtained.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light emitting device comprising:
an n-type semiconductor layer;
an active layer disposed on the n-type semiconductor layer;
a first p-type semiconductor layer disposed on the active layer and having an uneven structure formed on a surface thereof;
a second p-type semiconductor layer having an impurity concentration higher than that of the first p-type semiconductor layer, the second p-type second p-type semiconductor layer disposed on the first p-type semiconductor layer and having an uneven structure formed on a surface thereof; and
a reflective metal layer disposed on the second p-type semiconductor layer.

2. The semiconductor light emitting device of claim 1, wherein the uneven structure of the second p-type semiconductor layer has a shape corresponding to the uneven structure of the first p-type semiconductor layer.

3. The semiconductor light emitting device of claim 1, wherein the reflective metal layer has an uneven structure formed on a surface thereof.

4. The semiconductor light emitting device of claim 3, wherein the uneven structure of the reflective metal layer has a shape corresponding to the uneven structure of the second p-type semiconductor layer.

5. The semiconductor light emitting device of claim 1, further comprising a conductive substrate formed on the reflective metal layer.

6. The semiconductor light emitting device of claim 5, further comprising:
a conductive adhesive layer disposed between the reflective metal layer and the conductive substrate,
wherein the conductive adhesive layer is formed to fill the uneven structure of the reflective metal layer.

7. The semiconductor light emitting device of claim 5, further comprising:
at least one conductive via extending through the active layer, the first p-type semiconductor layer, the second p-type semiconductor layer, and the reflective layer to connect the n-type semiconductor layer and the conductive substrate.

8. The semiconductor light emitting device of claim 7, wherein the conductive via includes an uneven structure formed on an interface of the n-type semiconductor layer.

9. The semiconductor light emitting device of claim 7, further comprising:
an insulating region disposed between each of the active layer, the first p-type semiconductor layer, the second p-type semiconductor layer, and the reflective layer and the conductive vias.

10. The semiconductor light emitting device of claim 1, wherein the uneven structures of the first and second p-type semiconductor layers comprise a plurality of depressions and protrusions.

11. A method of forming a semiconductor light emitting device, the method comprising steps of:
disposing an n-type semiconductor layer on a substrate;
disposing an active layer on the n-type semiconductor layer;
disposing a first p-type semiconductor layer on the active layer;
disposing a mask having open regions exposing portions of an upper surface of the first p-type semiconductor layer on the first p-type semiconductor layer;
etching the first p-type semiconductor layer through the open regions to form an uneven structure;
disposing a second p-type semiconductor layer on the first p-type semiconductor layer such that the second p-type semiconductor layer has an impurity concentration higher than that of the first p-type semiconductor layer, the second p-type semiconductor layer having an uneven structure formed on a surface thereof; and
disposing a reflective metal layer on the second p-type semiconductor layer.

12. The method of claim 11, wherein the step of disposing the mask comprises:
disposing a metal layer on the first p-type semiconductor layer; and
making the metal layer cohere to form a plurality of clusters.

13. The method of claim 12, wherein the metal layer has a thickness ranging from 10 Å to 250 Å.

14. The method of claim 12, wherein the step of making the metal layer cohere is performed by thermally treating the metal layer.

15. The method of claim 12, wherein the disposing of the metal layer is performed through E-beam evaporation.

16. The method of claim 11, wherein the uneven structure of the second p-type semiconductor layer has a shape corresponding to the uneven structure of the first p-type semiconductor layer.

17. The method of claim 11, wherein the reflective metal layer has an uneven structure formed on a surface thereof.

18. The method of claim 17, wherein the uneven structure of the reflective metal layer has a shape corresponding to the uneven structure of the second p-type semiconductor layer.

19. The method of claim 11, further comprising the step of:
disposing a conductive substrate on the reflective metal layer.

20. The method of claim 11, further comprising the step of:
separating the substrate from the n-type semiconductor layer.

21. The method of claim 11, further comprising the step of:
removing the mask after forming the uneven structure by etching the first p-type semiconductor layer.

22. The method of claim 21, wherein the step of removing the mask comprises:
removing an oxide formed on a surface of the first p-type semiconductor layer.

23. The method of claim 11, wherein the uneven structures of the first and second p-type semiconductor layers comprise a plurality of depressions and protrusions.
